(19) United States
(12) Patent Application Publication
(10) Pub. No.: US 2005/0275089 A1
(43) Pub. Date: Dec. 15, 2005

(54) Package and method for packaging an integrated circuit die

(76) Inventors: Rajeev Dinkar Joshi, Cupertino, CA (US); Maria Cristina B. Estacio, Cebu City (PH); David Chong, Penang (MY); B. H. Gooi, Gelugor (MY); Stephen A. Martin, South Portland, ME (US)

Correspondence Address: Laurence S. Roach, Esq.;Law Office of Thomas R. FitzGerald, Suite 210, 16 E. Main Street, Rochester, NY, 14614-1803, US

(21) Appl. No.: 10/864,909

(22) Filed: Jun. 9, 2004

(51) Int. Cl. H01L 23/34; H01L 21/48

(52) U.S. Cl. 257/727; 257/690; 257/784; 438/117

(57) ABSTRACT

An integrated circuit assembly includes a lead frame having a plurality of leads with inner portions. A thermally-conductive clip member is bonded to the inner portions of the leads such that the clip member is electrically isolated from and yet thermally coupled to the lead frame. An integrated circuit die is bonded and thereby thermally coupled to the clip member. The die is electrically connected to the wire die by wire bonds. Encapsulant material is disposed over the inner portions of the leads and at least a portion of the clip member, and encapsulates the die and the wire bonds.

### FIELD OF THE INVENTION

The present invention relates generally to semiconductor devices and, more particularly, to a package for and method of packaging integrated circuit die.

### DESCRIPTION OF THE RELATED ART

Integrated circuit die are encapsulated within packages to protect the die and electrical interconnections thereto from the outside environment. One method of packaging an integrated circuit die generally includes the processes of bonding the die to a die paddle or pad of a lead frame. One configuration of such a package is often referred to as a micro-leaded package. After the die is bonded to the lead frame, the bond pads on the die are wire bonded to the inner leads or lead fingers of the lead frame, and the die, inner leads and bond wires are encapsulated in an encapsulant material.

The process of bonding the die to the paddle of the lead frame is typically accomplished by placing the die onto a layer of die attach material, such as, for example, an adhesive epoxy or thermoplastic, soft solder or a gold-silicon eutectic layer, that has been previously placed onto the paddle. The die attach material is preferably thermally conductive to thereby enable and/or enhance heat dissipation, and may or may not be electrically conductive. The process of wire bonding typically involves a wire bonding tool that forms bonds between the bonding wire and a bonding surface, i.e., the inner leads and/or the die bond pads, by compressing the bonding wire against that surface.

During the processes of die bonding and wire bonding the inner leads of the lead frame are typically clamped by a clamping mechanism to a heater block or other flat surface. The compressive force that occurs as a result of the wire bonding process may cause the unclamped die paddle and die mounted thereon to displace and/or bounce in a direction generally perpendicular to the lead frame and thereby undesirably impact the capability of the process of wire bonding to the die bond pads.

Die pads may be formed with a central opening to reduce the contact area between the die and the die paddle. Alternatively, the contract area between the die and lead frame is reduced by mounting the die directly upon the inner ends of the inner leads of the lead frame. Such a configuration, which is sometimes referred to as a chip-on-lead package configuration, leaves a large portion of the die unsupported and mounted above open space defined between the inner ends of the inner leads. Such openings between inner leads and/or within a die paddle, however, must be smaller than the mounting surface area of the die. Otherwise, the die is likely to be poorly supported or may simply fall through the opening. Such die bonding schemes can therefore only be used with certain die types and die sizes that have a contact surface area that is greater than the size of the open area. Thus, the benefits derived from reducing die size are to a significant degree offset by the need for a manufacturer to design and fabricate lead frames for each reduction in die size. Further, forming a central opening in a die pad increases the complexity and adds to the cost of producing such a lead frame.

Attaching the die to a tape which is then attached to the inner leads of the lead frame and over the opening addresses the above-described limitation of being able to use such a die bonding scheme with only dies having a surface area greater than the opening. However, the use of tape increases the process steps, complexity, and cost of the die bonding process. Further, since the tape is made from a different material than both the die and lead frame material, the problem of delamination may arise.

Regardless of whether the die is mounted directly or via tape to the lead frame, the die is to a substantial extent thermally isolated from the leads of the lead frame. Thus, the full surface area of the lead frame is not utilized to facilitate heat dissipation.

Therefore, what is needed in the art is an integrated circuit package and method of packaging that accommodates a variety of die sizes, enhances heat dissipation, and reduces thermal stress and delamination.

### SUMMARY OF THE INVENTION

The present invention provides a package for and method of packaging an integrated circuit die.

The invention comprises, in one form thereof, an integrated circuit assembly including a lead frame having a plurality of leads with inner portions. A thermally-conductive clip member is bonded to the inner portions of the leads such that the clip member is electrically isolated from and yet thermally coupled to the lead frame. An integrated circuit die is bonded and thereby thermally coupled to the clip member. The die is electrically connected to the leads by wire bonds. Encapsulant material is disposed over the inner portions of the leads and at least a portion of the clip member, and encapsulates the die and the wire bonds.

An advantage of the present invention is that an expanded range of die sizes is accommodated upon a single lead frame.

Another advantage of the present invention is that heat dissipation is significantly enhanced.

### BRIEF DESCRIPTION OF THE DRAWINGS

The above-mentioned and other features and advantages of this invention, and the manner of attaining them, will become apparent and be better understood by reference to the following description of one embodiment of the invention in conjunction with the accompanying drawings, wherein:

FIG. 1 is a cross-sectional view of an integrated circuit device including one embodiment of a package of the present invention;

FIG. 2 is a bottom view of the package of FIG. 1;

FIG. 3 is a cross-sectional view of an integrated circuit device including a second embodiment of a package of the present invention;

FIG. 4 is a bottom view of the package of FIG. 3;

FIG. 5 is a cross-sectional view of an integrated circuit device including a third embodiment of a package of the present invention;

FIG. 6 is a cross-sectional view of integrated circuit device including a second embodiment of a package of the present invention; and

FIG. 7 shows one embodiment of a method for fabricating an integrated circuit lead frame and package of the present invention.

Corresponding reference characters indicate corresponding parts throughout the several views. The exemplifications set out herein illustrate one preferred embodiment of the invention, in one form, and such exemplifications are not to be construed as limiting the scope of the invention in any manner.

### DETAILED DESCRIPTION OF THE DRAWINGS

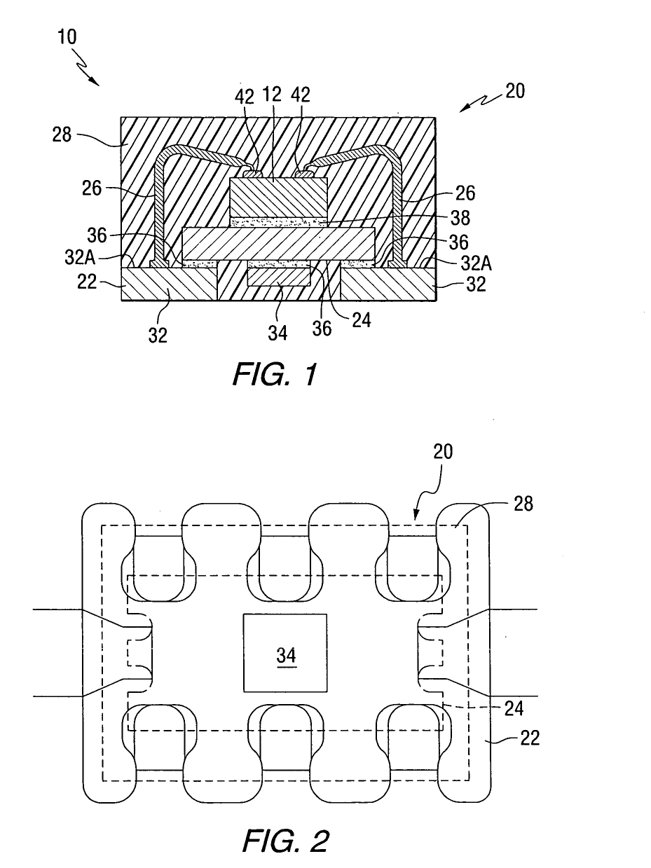

Referring now to the drawings, and particularly to FIGS. 1 and 2, an integrated circuit device including one embodiment of a package of the present invention is shown. Integrated circuit 10 generally includes die 12 and package 20. Integrated circuit 10 can be of virtually any size and configured as virtually any type of integrated circuit, such as, for example, a microprocessor or single transistor, dependent of course on the configuration of die 12. Die 12 is encapsulated within package 20.

Package 20 is, in the embodiment of FIGS. 1 and 2, configured as a micro-leaded package. However, it is to be understood that the present invention is compatible with virtually any type or configuration of integrated circuit package incorporating a lead frame. Package 20 includes lead frame 22, clip member 24, bond wires 26, and encapsulant material 28.

Lead frame 22 is a conventional lead frame having a plurality of leads 32 and a die pad 34 in a central portion thereof connected to lead frame 22 by tie bars (not shown), and is constructed of an electrically conductive material, such as copper or copper alloy or other suitable materials. Leads 32 have inner portions or ends 32A that are contained or encased within package 20 and outer portions thereof that extend and/or are disposed external to package 20 (not referenced).

Clip member 24 is disposed upon lead frame 22 such that at least the outer peripheral region thereof (not referenced) is disposed upon the inner portions or inner ends 34A of leads 32 and the central portion thereof is disposed upon die pad 34. Clip member 34 is bonded to lead frame 22 by a thermally conductive and electrically non-conductive adhesive paste or film 36, such as, for example, Ablebond 84-3 adhesive paste distributed by Emerson & Cuming. Thus, clip member 24 is thermally coupled to and yet electrically isolated from lead frame 22. Clip member 24 is constructed of either an electrically conductive material, such as, for example, copper, or a non-conductive material, such as, for example, silicon. Forming clip member 24 of the same material or from a material having a coefficient of thermal expansion (CTE) that is approximately equal to the material from which die 12 is formed reduces thermal stress between the two and thus reduces thermally-induced delamination and cracking.

Die 12 is a conventional integrated circuit die, and is disposed on the side of clip member 24 opposite the side thereof that is bonded to lead frame 22. Die 12 is bonded to clip member 24 by a thermally conductive and an electrically non-conductive paste or film 38, such as, for example, Ablebond 84-3 adhesive paste distributed by Emerson & Cuming. Thus, die 12 is thermally coupled to, and yet electrically isolated from, clip member 24. Bond wires 26 electrically connect die bond pads 42 on die 12 to corresponding leads 32 of lead frame 22. After the wire bonding process, ecapsulant material 28 is formed, such as, for example, via transfer molding, around the inner portions 32A of lead frame 22, die 12 and bond wires 26 to thereby form an encapsulated package 20.

As discussed above, die pad 34 is connected to lead frame 22 by tie bars (not shown). Typically, such tie bars do not provide uniform support of the die. It should be particularly noted, however, that by bonding die 12 to clip member 34 which, in turn, is disposed upon and bonded to the inner portions or ends 32A of leads 32 and to die pad 34, clip member 24 provides uniform support to die 12 on all sides thereof. Such uniform support significantly reduces bouncing of the die/die pad during the wire bonding process. Further, by bonding die 12 to clip member 24 which, in turn, is disposed upon and bonded to the inner portions or ends 32A of leads 32 and to die pad 34, a common die pad size can be used for many different die sizes and die types, thereby reducing the number of different package types and lead frames that must be produced and inventoried by a manufacturer.

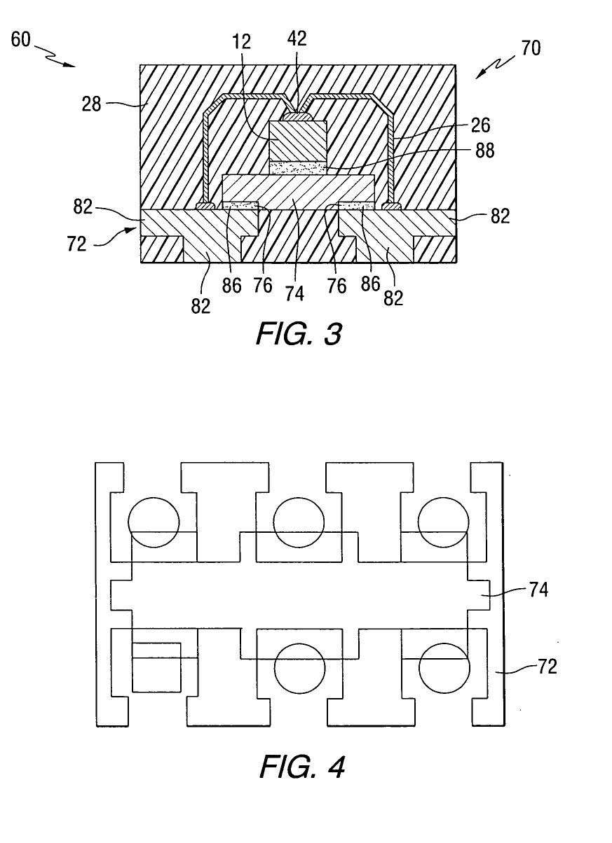

Referring now to FIGS. 3 and 4, an integrated circuit device including another embodiment of a package of the present invention is shown. Integrated circuit 60 is generally similar to integrated circuit 10 and corresponding reference characters are used to indicate corresponding parts. Integrated circuit 60 includes die 12 and package 70. Package 70 includes lead frame 72, clip member 74, bond wires 26, and encapsulant material 28. Lead frame 72 includes leads 82 and is, in contrast to lead frame 22 of package 20, configured as a chip-on-lead lead frame without a die attach paddle. Clip member 74 includes recessed regions or flats 76 around the peripheral of the surface thereof that is opposite the side thereof upon which die 12 is disposed. The flats 76 receive the inner portions or ends of leads 82 of lead frame 72 and are bonded thereto by a thermally conductive and electrically non-conductive paste or film 86.

Die 12 is bonded to clip member 74 by a thermally conductive and an electrically non-conductive paste or film 88, such as, for example, Ablebond 84-3 adhesive paste distributed by Emerson & Cuming. Thus, die 12 is thermally coupled to, and yet electrically isolated from, clip member 74. Bond wires 26 electrically connect die bond pads 42 on die 12 to corresponding leads 82 of lead frame 72. After the wire bonding process, encapsulant material 28 is formed to thereby form encapsulated package 70 in substantially the same manner as described above in regard to package 20.

It should be noted that the bonding of clip member 74 to lead frame 72 forms a lead frame and/or packaging subassembly that expands the range of die sizes with which lead frame 72 is compatible. Dies that might otherwise have been too small for being suitably bonded to lead frame 72 are now easily and suitably bonded to lead frame 72 via clip member 74.

In this chip-on-lead embodiment, lead frame 22 has no dedicated die pad. Therefore, lead frame 22 would normally be limited to use with die of a particular minimum size or range of sizes and of a particular die type. Die less than the particular minimum size would be inadequately supported upon the ends or inner portions of leads 82 and/or fall completely through the space therebetween. It should be particularly noted, however, that by bonding die 12 to clip member 74 which, in turn, is disposed upon and bonded to the inner portions or ends of leads 82, clip member 74 provides uniform support to die 12 on all sides thereof. Such uniform support significantly reduces bouncing of the die during the wire bonding process. Further, bonding die 12 to clip member 74 which, in turn, is then disposed upon and bonded to lead frame 72 prevents smaller die from being inadequately supported upon and/or falling through the central void of lead frame 72 and thereby enables the use of a broader range of (i.e., smaller) die sizes and types with lead frame 72 than otherwise possible.

It should also be particularly noted that recessed or coined regions 76 reduce the overall height of package 70, or reduce the height of die 12 within package 70, and thereby provide either a lower profile package and/or additional clearance between bond wires 26 and the outer surface of encapsulant material 28 and/or package 70.

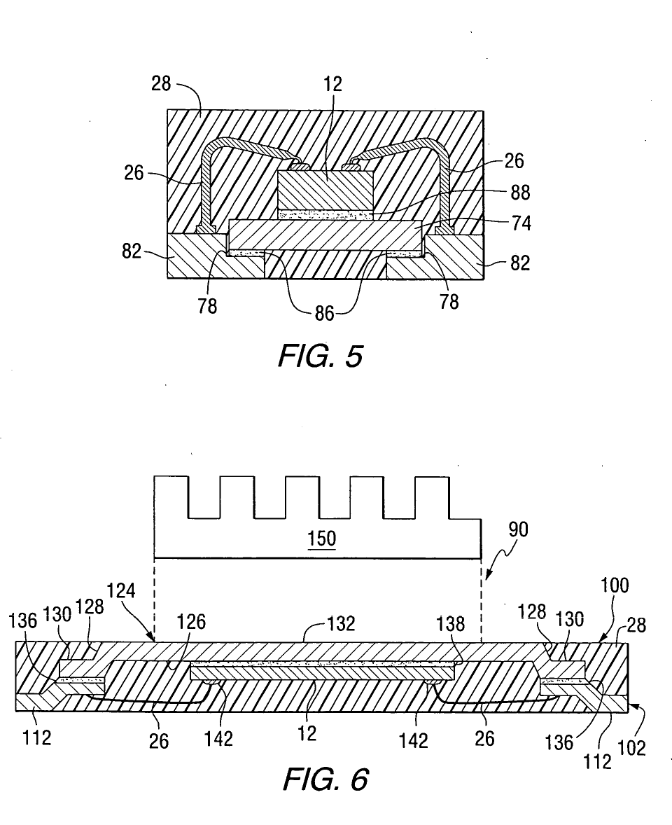

In the embodiment shown in FIGS. 3 and 4, clip member 74 includes recessed regions or flats 76 around the peripheral thereof and which receive the inner portions or ends of leads 82 of lead frame 72. However, as shown in FIG. 5, the present invention can be alternately configured with similar flats 78 formed on the inner portions or ends of leads 82 and which receive a peripheral portion of clip member 74.

Referring now to FIG. 6, an integrated circuit device including another embodiment of a package of the present invention is shown. Integrated circuit 90 is generally similar to integrated circuits 10 and 60, and corresponding reference characters are used to indicate corresponding parts. Integrated circuit 90 includes die 12 and package 100. Package 100 includes lead frame 102, clip member 124, bond wires 26, and encapsulant material 28. Lead frame 102 includes leads 112 and is configured as a micro-leaded lead frame.

In this embodiment, clip member 124 functions as both a die attach paddle and a heat sink attach/interface surface. More particularly, clip member 124 includes a central pad area 126 interconnected by stepped regions 128 to flats 130, and an interface surface 132 on the side of clip member 124 that is opposite the side upon which central pad area 126 is disposed. Flats 130 are bonded by a thermally conductive and an electrically non-conductive paste or film 136, such as, for example, Ablebond 84-3 adhesive paste distributed by Emerson & Cuming, to the inner portion or ends of leads 112 of lead frame 102 to thereby bond clip member 124 to lead frame 102.

Die 12 is bonded to central pad area 126 of clip member 124 by a thermally conductive and an electrically non-conductive paste or film 138, such as, for example, Ablebond 84-3. Thus, die 12 is thermally coupled to, and yet electrically isolated from, clip member 124. Bond wires 26 electrically connect die bond pads 142 on die 12 to the inner portion or ends of corresponding leads 112 of lead frame 102.

After the wire bonding process, encapsulant material 28 is formed to thereby form encapsulated package 100 in generally the same manner as described above in regard to packages 20 and 70. However, in this embodiment, it should be particularly noted that at least a portion of interface surface 132 is not encapsulated by encapsulant material 28, i.e., a portion of interface surface 132 is exposed to an exterior of package 100. The exposed portion of interface surface 132 provides a surface to which a heatsink, such as heatsink 150, can be attached.

It should also be particularly noted that by using clip 124 as both the die attach pad and a heat sink attach interface simplifies the design and manufacture of lead frame 102 and maximizes the area of die attach pad 126 by eliminating the two-step downset used in conventional lead frames.

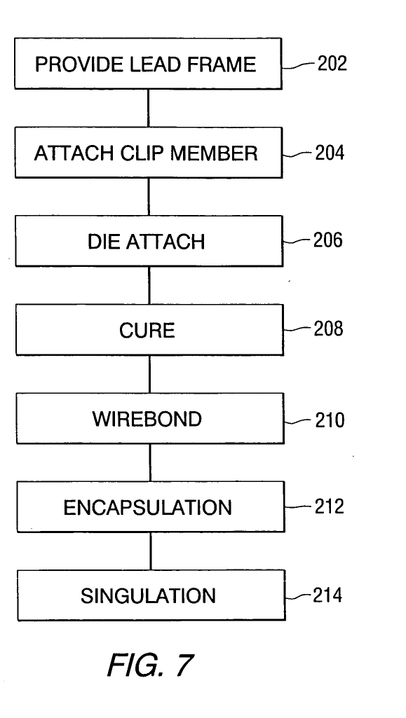

Referring now to FIG. 7, one embodiment of a method for fabricating an integrated circuit lead frame and package of the present invention is shown. Method 200 includes the steps of providing a lead frame 202, attaching clip member 204, die attach 206, cure 208, wirebonding 210, encapsulation 212 and singulation 214.

The process of providing lead frame 202 includes providing a lead frame to the process of attaching clip member 204. Attaching clip member 204 includes the process of placing a thermally conductive but electrically non-conductive film or paste, such as film/paste layer 36, 86, or 136, onto at least one of the surfaces of a clip member, such as clip member 24, 74 or 124, and/or a lead frame, such as lead frame 22, 72 or 102, and disposing the appropriate surfaces thereof in proper alignment and in engagement with each other. Similarly, the process of die attach 206 includes placing a layer of film or paste, such as film/paste layer 38, 88 or 138, onto the appropriate areas of a clip member, such as clip member 24, 74 or 124, and picking and placing a die, such as die 12, onto that layer of film or paste.

The process of cure 208 generally involves exposing the partially-completed package assembly to conditions of elevated temperature and other controlled environmental conditions sufficient to cure the layers of film/paste and which are known to those of ordinary skill in the art of integrated circuit packaging. The process of wirebonding 210, as will also be known to those of ordinary skill in the art, involves bonding one end of a bond wire to a bond pad on the die, such as die bond pad 42, and the other end to a corresponding inner portion or end of the inner leads of the lead frame. The process of encapsulation typically involves transfer molding or otherwise encapsulating with a plastic material the inner portions of the leads of the lead frame, the bond wires, and the die to thereby form an integrated circuit package. The process of singulation 214 is similarly known to those or ordinary skill in the art of integrated circuit fabrication.

In the embodiment shown, the clip member is attached or bonded to the ends of the inner leads and/or to a die pad of the lead frame. However, it is to be understood that the clip member, in addition to being bonded to the ends of the inner leads and/or to the die pad of the lead frame as shown and described, can also be bonded to one or more tie bars of the lead frame.

While this invention has been described as having a preferred design, the present invention can be further modified within the spirit and scope of this disclosure. This application is therefore intended to cover any variations, uses, or adaptations of the present invention using the general principles disclosed herein. Further, this application is intended to cover such departures from the present disclosure as come within the known or customary practice in the art to which this invention pertains and which fall within the limits of the appended claims.

1. An integrated circuit assembly, comprising:
a lead frame having a plurality of leads with inner portions;
a thermally-conductive clip member bonded to said inner portions of said leads, said clip member being electrically isolated from and thermally coupled to said lead frame;
an integrated circuit die bonded to said clip member, said die being thermally coupled to said clip member;
wire bonds electrically interconnecting said die to said lead frame; and
encapsulant material disposed over said inner portions of said leads and at least a portion of said clip member, and encapsulating said die and said wire bonds.

2. The integrated circuit assembly of claim 1, wherein said clip member is thermally bonded to each of said plurality of leads.

3. The integrated circuit assembly of claim 1, wherein said lead frame further includes a die attach paddle, said clip member being thermally bonded to at least some of said plurality of leads and to said die attach paddle.

4. The integrated circuit assembly of claim 1, wherein said clip member is constructed of a material having a coefficient of thermal expansion that is approximately equal to the coefficient of thermal expansion of the material from which said integrated circuit die is constructed.

5. The integrated circuit assembly of claim 1, wherein said clip member consists substantially of the same material from which said integrated circuit die is primarily constructed.

6. The integrated circuit assembly of claim 1, wherein said clip member consists substantially of silicon.

7. The integrated circuit assembly of claim 1, wherein said clip member consists substantially of copper.

8. The integrated circuit assembly of claim 1, wherein said encapsulant material entirely encapsulates said clip member.

9. The integrated circuit assembly of claim 1, wherein said clip member includes a first side and a second side opposite said first side, said die bonded to said first side, said encapsulate exposing at least a portion of said second side.

10. The integrated circuit assembly of claim 9, further comprising a heat sink thermally coupled to the exposed portion of said second side.

11. The integrated circuit assembly of claim 1, wherein said die is electrically coupled to said clip member.

12. The integrated circuit assembly of claim 1, wherein said clip member includes recessed flats, said recessed flats receiving and being disposed upon corresponding said inner portions of said leads and being thermally bonded thereto.

13. The integrated circuit assembly of claim 1, wherein said inner portions of said leads include recessed flats, a peripheral portion of said clip member being received and disposed within said recessed flats and being thermally bonded thereto.

14. A packaging subassembly for an integrated circuit, comprising:
a lead frame having a plurality of leads with inner portions; and
a thermally-conductive clip member bonded to said inner portions of said lead frame, said clip member being electrically isolated from and thermally coupled to said lead frame, said clip member configured for having an integrated circuit die bonded and thermally coupled thereto.

15. The packaging subassembly of claim 14, wherein said clip member is thermally bonded to each of said plurality of leads.

16. The integrated circuit assembly of claim 14, wherein said lead frame further includes a die attach paddle, said clip member being thermally bonded to at least some of said plurality of leads and to said die attach paddle.

17. The integrated circuit assembly of claim 14, wherein said clip member consists substantially of silicon.

18. The integrated circuit assembly of claim 14, wherein said clip member consists substantially of copper.

19. The integrated circuit assembly of claim 14, wherein said clip member includes recessed flats, said recessed flats receiving and being disposed upon corresponding said inner portions of said leads and being thermally bonded thereto.

20. The integrated circuit assembly of claim 14, wherein said inner portions of said leads include recessed flats, a peripheral portion of said clip member being received and disposed within said recessed flats and being thermally bonded thereto.

21. A method of coupling an integrated circuit die to a heat-dissipating structure, comprising:
providing a lead frame having a plurality of leads with inner portions;
bonding a thermally-conductive clip member to the inner portions of the leads that the clip member is electrically isolated from and thermally coupled to the lead frame; and
bonding an integrated circuit die to a first side of the clip member in a thermally conductive manner, the die being thermally coupled by the clip member to the lead frame, the lead frame dissipating heat generated by the die and thereby comprising at least a part of the heat-dissipating structure.

22. The method of claim 21, comprising the further step of:
encapsulating the die, the wire bonds, the inner portions of the leads and a portion of a second side of said clip member in an encapsulant material, the second side of the clip member being opposite to the first side of the clip member to which the die is bonded, an exposed portion of the second side not being encapsulated by the encapsulant material; and
thermally coupling a heat sink to the exposed portion of the second side of the clip member, the heat sink thereby comprising a portion of the heat-dissipating structure.

23. A method of fabricating a package for an integrated circuit, comprising:
providing a lead frame having a plurality of leads with inner portions;
bonding a thermally-conductive clip member to the inner portions of the leads such that the clip member is electrically isolated from and thermally coupled to the lead frame;
bonding an integrated circuit die to a first side of the clip member such that the die is thermally coupled to the clip member;
wire bonding the die to the leads of the lead frame; and
encapsulating the die, the wire bonds, the inner portions of the leads, and at least a portion of the clip member in an encapsulant material.

24. The method of claim 23, comprising the further steps of:
exposing a portion of a second side of the clip member, the second side of the clip member being opposite the first side thereof to which the die is bonded; and
thermally coupling a heat sink to the exposed portion of the second side of the clip member.

25. The method of claim 24, wherein said exposing step comprises not encapsulating the exposed portion of the second side of the clip member in the encapsulant material.

26. A method for bonding an integrated circuit die to an otherwise oversized lead frame, the lead frame having a plurality of leads with inner portions, the method comprising:
bonding a thermally-conductive clip member to the inner portions of the leads such that the clip member is electrically isolated from and thermally coupled to the lead frame; and
bonding the integrated circuit die to a first side of the clip member such that the die is thermally coupled to the clip member.
